(19) United States
(12) Patent Application Publication
(10) Pub. No.: US 2009/0249996 A1
(43) Pub. Date: Oct. 8, 2009

(54) Silicon single crystal pulling method

(76) Inventor: Hideki Watanabe, Tokyo (JP)

Correspondence Address: CLARK & BRODY, 1090 VERMONT AVENUE, NW, SUITE 250, WASHINGTON, DC, 20005, US

(21) Appl. No.: 12/385,385

(22) Filed: Apr. 7, 2009

(30) Foreign Application Priority Data
Apr. 8, 2008 (JP) 2008-100339

(51) Int. Cl. C30B 15/10

(52) U.S. Cl. 117/32; 117/35

(57) ABSTRACT

Until pulling a silicon single crystal is started after silicon raw materials filled in a quartz crucible are melted, the quartz crucible containing silicon melt is rotated while a rotating direction thereof is periodically alternated. Then, the silicon single crystal is pulled up by the CZ method. This pulling method can reduce micro defects, which are caused by bubbles formed in an inner surface of the quartz crucible, and dislocation in the single crystal.

### BACKGROUND OF THE INVENTION

1. Field of the Invention

The present invention relates to a silicon single crystal pulling method which is applied for growing a silicon single crystal performed by the Czochralski method (hereinafter referred to as “CZ method”). More particularly, the invention relates to a silicon single crystal pulling method in which “micro defects created in the silicon single crystal by bubbles formed in a surface of a quartz crucible in connection with melting of a silicon raw material” (hereinafter simply referred to as “micro defect”)and a dislocated silicon single crystal in an initial stage of the pulling method can be reduced.

2. Description of the Related Art

A single crystal pulling method of the CZ method is widely used to grow the silicon single crystal which is of the source material of the semiconductor silicon wafer. In the growth of the silicon single crystal by the CZ method, polycrystalline silicon as raw material is melted in a quartz crucible placed in a central portion of a pulling apparatus, and a silicon melt is formed in the crucible. A seed crystal is dipped in the silicon melt, and then the seed crystal is vertically pulled up while the seed crystal and the quartz crucible are rotated, thereby growing the silicon single crystal beneath the seed crystal.

In the silicon single crystal growth, because of various shapes of silicon raw materials, the melting is started while lump-like raw materials are arranged in an upper portion of the quartz crucible in order to prevent damage of quartz crucible caused by subsidence of the raw material during the melting. However, since the subsidence of the raw material inevitably takes place in the melting process, scratches are to be generated in an inner surface of the quartz crucible, and bubbles are formed at the scratches as initiation point and adhere to the inner surface of the crucible.

Besides, since the quartz crucible is molded at a high temperature in an inert atmosphere, the bubbles remain in the inner surface or adjacent to the inner surface in the process of producing the crucible, and the bubbles emerge with melting of silicon raw materials and adhere to the inner surface of the crucible.

The bubbles generated in the surface of the quartz crucible are grown to predetermined sizes and extricated. In the process of growing the silicon single crystal, when the bubbles reach a crystal growth interface to be taken in the single crystal, micro defects may be generated in the grown single crystal or the single crystal may be caused to have dislocation due to the bubbles. Recently, with development of miniaturization of an integrated circuit, attention is focused on micro defects in a silicon wafer as a quality problem. In cases where a single crystal with dislocation is generated during the growth, the pull-up of the single crystal is interrupted, and it is necessary to perform a melt-back operation in which the single crystal is moved downward and remelted into the silicon melt of the crucible, which remarkably lowers efficiency of the silicon single crystal growth.

Conventionally, in order to solve the problem caused by the bubbles in the silicon melt, Japanese Patent No.2635456, for example, proposes a combination operation of low-pressure melting and high-pressure pulling, in which the polycrystalline silicon raw material is melted in an atmosphere at a low pressure ranging from 5 to 60 mbar, and the single crystal is pulled up in an atmosphere at a high pressure of 100 mbar or more.

In the operation proposed by Japanese Patent No. 2635456, when the silicon raw materials are melted under the reduced pressure, buoyancy of the bubbles existing in the silicon melt is increased, while gas solubility of the melt is decreased, so that the bubbles are easily dissipated from the melt surface to decrease the amount of bubbles included in the melt. Therefore, an incidence rate of crystal defects caused by the bubbles can be reduced.

Since the inner surface of the quartz crucible is exposed to the high-temperature silicon melt, hardly-soluble substances are generated in an interface with the silicon melt, and the quartz crucible is deteriorated due to extrication of the hardly-soluble substances. The single crystal with dislocation is generated when the hardly-soluble substances are extricated and adhere to the surface of the pulling silicon single crystal.

In a method proposed by Japanese Patent No. 3598634, by applying a magnetic field to the quartz crucible in which the silicon melt is filled before growing the silicon single crystal, a melting rate in the quartz crucible is enhanced to hardly allow the hardly-soluble substances to be generated, and the deteriorated inner surface of the crucible is repaired to prevent the dislocation from occurring in the silicon single crystal due to the deterioration of the inner surface of the crucible.

### SUMMARY OF THE INVENTION

In the combination operation of the low-pressure melting and the high-pressure pulling proposed by Japanese Patent No. 2635456, the problems such as the micro defects and the dislocation caused in the single crystal l by the generated bubbles in the low-pressure operation during the melting can be solved to some extent. However, the problems such as the micro defects in the single crystal and the dislocation in the single crystal generated in the high-pressure operation during pulling the single crystal cannot be solved. Therefore, the yield of the single crystal is not much improved as a whole in the combination operation of the low-pressure melting and the high-pressure pulling.

In the method proposed by Japanese Patent No. 3598634, although the dislocation of the single crystal caused by the deteriorated inner surface of the crucible can be prevented, the gas contained in the quartz crucible is easily transformed as the bubbles in the surface of the quartz crucible since the melting rate in the quartz crucible is heightened. Accordingly, micro defects attributable to the bubbles are easily generated in the grown single crystal.

In view of the foregoing, an object of the present invention is to provide a silicon single crystal pulling method in which micro defects in the single crystal due to the bubbles formed in the surface of the quartz crucible and the dislocation in the single crystal can be reduced without lowering the efficiency of the silicon single crystal growth.

In order to achieve the above object, the present inventor paid attention to the fact that the quartz crucible can be rotated and the rotating direction thereof can be inverted, and obtains the following findings as a result of study of a method for removing the bubbles adhering to the inner surface of the quartz crucible in which the silicon melt is contained.

The rotation of the quartz crucible in which the silicon melt is contained generates a flow of the silicon melt along a side surface and a bottom surface of the quartz crucible. In the case where the quartz crucible is unidirectionally rotated, the bubbles still adhere to the inner surface of the crucible since the rotating direction of the quartz crucible is the same with that of the flowing direction of the silicon melt. In this regard, when the rotating direction of the quartz crucible is alternated, an inertia force is applied to the silicon melt immediately after the alternated rotation, and the quartz crucible rotates in the direction opposite to the flow of the silicon melt. At this point, shearing force is generated in the interface between the quartz crucible and the silicon melt and in the neighborhood of the interface, whereby the bubbles can be removed from the inner surface of the quartz crucible so as to be ripped off. Before the bubbles sequentially generated in the inner surface of the quartz crucible are grown, the bubbles can repeatedly be removed by periodically performing alternating direction of rotation.

Additionally, the flow of the silicon melt is suppressed by applying the magnetic field to the quartz crucible in which the silicon melt is contained. Accordingly, a frictional force is increased between the silicon melt and the quartz crucible, and the shearing force is also increased immediately after the rotating direction of the quartz crucible is inverted, so that the efficiency of the removal of the bubbles from the inner surface of the quartz crucible can be improved. Further, scratches which become initiation points of the bubble generation can be removed in the inner surface of the quartz crucible by the increased frictional force.

The present invention is made based on the above-described findings. An aspect of the invention provides a silicon single crystal pulling method performed by the Czochralski method, in which a quartz crucible containing silicon melt is rotated while a rotating direction thereof is periodically inverted until pulling a silicon single crystal is started after a silicon raw material filled in the quartz crucible is melted.

The start of pulling a silicon single crystal as used herein means the start of an operation in which the seed crystal is dipped in the silicon melt and the single crystal is pulled up. That is, the invention is characterized in that the operation in which the quartz crucible is rotated while the rotating direction thereof is periodically alternated is performed until the seed crystal is dipped in the silicon melt.

In the silicon single crystal pulling method according to the aspect of the invention, it is preferable that a magnetic field is applied to the quartz crucible.

In addition, it is preferable that a rotation rate of the quartz crucible ranges from 5 rpm to 15 rpm, and further preferable that a rotation rate of the quartz crucible ranges from 0.5 rpm to 15 rpm and an alternate rotation time period of the quartz crucible is equal to or more than 10 sec.

In case of applying a magnetic field, intensity of the magnetic field applied to the quartz crucible preferably ranges from 100 Gauss to 3000 Gauss. A time interval of the operation in which the quartz crucible is rotated while the rotating direction thereof is periodically alternated preferably ranges from 600 sec to 6000 sec. Therefore, the scratches in the inner surface of the crucible, which are initiation points of the bubble generation, can assuredly be repaired.

According to the silicon single crystal pulling method of the present invention, the bubbles adhering to the inner surface of the quartz crucible in which the silicon melt is contained can be removed before the growth of the silicon single crystal by the CZ method is started. Accordingly, the micro defects caused by the bubbles in the silicon single crystal and the dislocation in the silicon single crystal can be reduced without lowering the efficiency of the silicon single crystal growth.

### BRIEF DESCRIPTION OF THE DRAWING

FIG. 1 shows an entire configuration of a pulling apparatus to which a silicon single crystal pulling method according to an embodiment of the invention can be applied.

### DETAILED DESCRIPTION OF THE PREFERRED EMBODIMENTS

A silicon single crystal pulling method according to the present invention will be described with reference to the drawing.

In the silicon single crystal pulling method of the present invention, a quartz crucible can be rotated about a pulling axis of a single crystal, and pulling the silicon single crystal is started after the quartz crucible containing the silicon melt is rotated while the rotating direction thereof is periodically inverted.

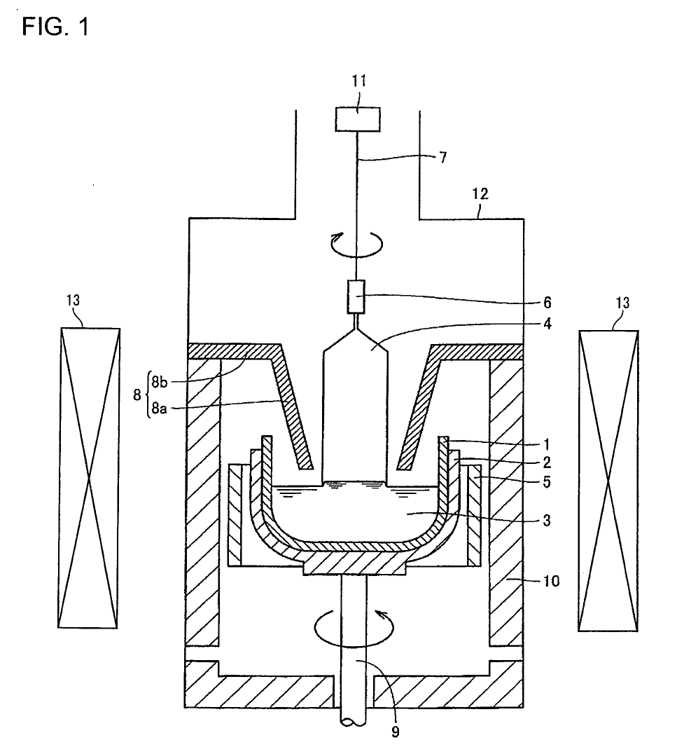

FIG. 1 shows an entire configuration of a pulling apparatus to which the silicon single crystal pulling method according to the present invention can be applied. A quartz crucible 1 in which silicon melt 3 is accommodated is provided in a chamber 12 constituting a framework of a silicon single crystal pulling apparatus, and an outer peripheral surface and an outer bottom surface of the quartz crucible 1 are held by a graphite susceptor 2. The graphite susceptor 2 is fixed to an upper end of a support shaft 9 which is parallel to a vertical direction. The quartz crucible 1 is rotated in a predetermined direction by means of the support shaft 9, while permitted to vertically move.

The quartz crucible 1 and the graphite susceptor 2 are surrounded by a heater 5, and the heater 5 is surrounded by a heat insulating cylinder 10. In a process for melting raw materials during the silicon single crystal growth, high-purity silicon raw materials with which the quartz crucible 1 is filled are heated by the heater 5 and melted into the silicon melt 3.

On the other hand, pulling means 11 is provided at the upper end of the chamber 12 of the pulling apparatus. A wire cable 7 is attached to the pulling means 11 while hanging down toward the rotation center of the quartz crucible 1, and a pulling motor (not shown) is provided in the pulling means 11 so as to wind or pay out the wire cable 7. A seed crystal 6 is attached to a lower end of the wire cable 7.

In the pulling apparatus, a cylindrical heat shielding member 8 is provided between a silicon single crystal 4 and the heat insulating cylinder 10 so as to surround the growing silicon single crystal 4. The heat shielding member 8 includes a cone portion 8a and a flange portion 8b, and is disposed at a predetermined position by attaching the flange portion 8b to the heat insulating cylinder 10.

Outside the chamber 12, magnetic field applying devices 13 including electromagnet coils are disposed so as to face each other with the quartz crucible 1 being interposed therebetween in order to apply the magnetic field to the silicon melt in the quartz crucible 1.

The silicon single crystal pulling method of the present invention can be applied to the pulling apparatus shown in FIG. 1. The pulling method will be described below.

### <Melting Process>

In a step of melting the silicon raw material, the quartz crucible 1 is filled with high-purity silicon raw materials, and the silicon raw materials are heated to a temperature of a silicon melting point or more and melted by the heater 5, and the silicon melt 3 is contained in the quartz crucible 1.

### <Bubble Removing Process>

Next, the quartz crucible 1 in which the silicon melt 3 is contained is rotated while the rotating direction thereof is periodically alternated. When the quartz crucible 1 is rotated, a flow of the silicon melt 3 is generated along a side surface and a bottom surface of the quartz crucible 1. Immediately after the repeated alternated rotation of the quartz crucible 1, an inertia force is applied to the silicon melt 3, and the quartz crucible rotates in the opposite direction to the flow of the silicon melt 3, thereby repeatedly generating a shearing force in an interface between the quartz crucible 1 and the silicon melt 3 and the neighborhood of the interface. The bubbles adhering to the inner surface of the quartz crucible 1 are ripped off by the shearing force, and the bubbles are removed from the silicon melt 3.

### <Growing Process>

Then, the seed crystal 6 is dipped in the silicon melt 3 in which the bubbles are removed, and the seed crystal 6 is pulled up while the wire cable 7 is rotated, thereby growing the cylindrical silicon single crystal 4. At this point, the quartz crucible 1 is rotated in a direction opposite to the rotation of the wire cable 7.

Thus, according to the silicon single crystal pulling method of the present invention, before the growth of the silicon single crystal 4 is started, the bubbles can be removed from the silicon melt 3 by taking off the bubbles adhering to the inner surface of the quartz crucible 1. Accordingly, the micro defects caused by the bubbles in the silicon single crystal and the dislocation in the silicon single crystal can be reduced without lowering the growth efficiency of the silicon single crystal 4 in the growing process.

In said bubble removing process, it is preferable that the rotation rate of the quartz crucible 1 ranges from 5 rpm to 15 rpm. Further, it is preferable that the rotation rate of the quartz crucible 1 ranges from 0.5 rpm to 15 rpm and the alternated rotation period is equal to or more than 10 sec. When the rotation rate is less than 0.5 rpm, the flow of the silicon melt 3 is not sufficiently generated along the side surface and bottom surface of the quartz crucible 1 irrespective of the alternated rotation period. Also when the rotation rate is less than 5 rpm and the alternated rotation period is less than 10 sec, the flow of the silicon melt 3 along the side surface and bottom surface of the quartz crucible 1 is not sufficiently generated. When the rotation rate is more than 15 rpm, said flow of the silicon melt 3 is largely disturbed, and the bubbles adhering to the inner surface of the quartz crucible 1 cannot sufficiently be taken off.

In the bubble removing process, the magnetic field may be applied to the rotating quartz crucible 1 with the magnetic field applying devices 13. Frictional force is increased between the silicon melt 3 and the quartz crucible 1 by applying the magnetic field, and shearing force is also increased immediately after the rotating direction of the quartz crucible 1 is alternated, so that efficiency of the removal of the bubbles from the inner surface of the quartz crucible 1 can be improved. In addition, the increased frictional force removes the scratches in the inner surface of the quartz crucible 1, which becomes the initiation points of the bubble generation, so that the bubbles can be reduced.

In applying the magnetic field, the magnetic field intensity is preferably equal to or less than 3000 Gauss, and more preferably in the range of 500 Gauss to 3000 Gauss. When the magnetic field intensity is less than 500 Gauss, the effect of the bubble removal and the effect of the removal of scratches in the inner surface of the quartz crucible 1, which are attributed to the increase in frictional force, are not sufficiently improved. On the other hand, when the magnetic field intensity is more than 3000 Gauss, the frictional force becomes excessive, and the inner surface of the quartz crucible 1 is excessively scraped off to induce a rugged inner surface. In this regard, the rugged inner surface of the quartz crucible 1 generates vibration in the surface of the silicon melt 3 when the quartz crucible 1 is rotated, and the vibration causes dislocation in the silicon single crystal 4 in the growing process.

### EXAMPLE

The following pulling test was performed in order to confirm the effect of the silicon single crystal pulling method of the present invention, and results thereof were evaluated.

### (a) Pulling Conditions

In the test of the example, the single crystal was grown using the pulling apparatus shown in FIG. 1. The 160-kg polycrystalline silicon as raw material loaded in the quartz crucible was heated and melted in the melting process, the bubbles adhering to the inner surface of the quartz crucible was removed in the bubble removing process, and the silicon single crystal having a diameter of 200 mm was pulled up from the silicon melt in the growing process.

The silicon raw materials are in a cylindrical shape, a conical shape, and a lump-like form. A combination ratio of the cylindrical shape, the conical shape and the lump-like form, and each loading position in the quartz crucible were identically set for all the tests. The quartz crucibles with the same characteristics were used in all the tests.

After the silicon raw materials were completely melted, the quartz crucible was rotated in the bubble removing process, and the rotating direction was alternated 10 times. Table 1 shows the conditions of the rotation rate, the alternated rotation period, and the magnetic field intensity of the quartz crucible at this point. However, the conventional method was adopted for Test No. 1, in which the quartz crucible was held at the rotation rate of 1 rpm for 600 seconds without alternating direction of rotation.

In each test, the five silicon single crystals were pulled up from the silicon melt in which the bubble removing process was completed.

TABLE 1

| | | Alternated | | |
|---|---|---|---|---|
| | Rotation | rotation | Magnetic field | Incidence rate |
| Test | rate | period | intensity | of micro |
| No. | (rpm) | (sec) | (Gauss) | defects |
| 1 | 1 | 0 | 0 | — |
| 2 | 0.1 | 5 | 0 | Δ |
| 3 | 0.1 | 10 | 0 | Δ |
| 4 | 0.1 | 30 | 0 | Δ |
| 5 | 0.1 | 600 | 0 | Δ |
| 6 | 0.1 | 10 | 100 | Δ |
| 7 | 0.1 | 10 | 500 | Δ |
| 8 | 0.1 | 10 | 1000 | Δ |
| 9 | 0.1 | 10 | 3000 | Δ |
| 10 | 0.1 | 10 | 5000 | Δ |
| 11 | 0.5 | 5 | 0 | Δ |
| 12 | 0.5 | 10 | 0 | ∘ |
| 13 | 0.5 | 30 | 0 | ∘ |
| 14 | 0.5 | 600 | 0 | ∘ |
| 15 | 0.5 | 10 | 100 | ∘ |
| 16 | 0.5 | 10 | 500 | ∘ |
| 17 | 0.5 | 10 | 1000 | ∘ |
| 18 | 0.5 | 10 | 3000 | ∘ |
| 19 | 0.5 | 10 | 5000 | Δ |
| 20 | 5 | 5 | 0 | ∘ |
| 21 | 5 | 10 | 0 | ∘ |
| 22 | 5 | 30 | 0 | ∘ |
| 23 | 5 | 600 | 0 | ∘ |
| 24 | 5 | 10 | 100 | ∘ |
| 25 | 5 | 10 | 500 | ∘ |
| 26 | 5 | 10 | 1000 | ∘ |
| 27 | 5 | 10 | 3000 | ∘ |
| 28 | 5 | 10 | 5000 | Δ |
| 29 | 15 | 5 | 0 | ∘ |
| 30 | 15 | 10 | 0 | ∘ |
| 31 | 15 | 30 | 0 | ∘ |
| 32 | 15 | 600 | 0 | ∘ |
| 33 | 15 | 10 | 100 | ∘ |
| 34 | 15 | 10 | 500 | ∘ |
| 35 | 15 | 10 | 1000 | ∘ |
| 36 | 15 | 10 | 3000 | ∘ |
| 37 | 15 | 10 | 5000 | Δ |
| 38 | 20 | 5 | 0 | Δ |
| 39 | 20 | 10 | 0 | Δ |
| 40 | 20 | 30 | 0 | Δ |
| 41 | 20 | 600 | 0 | Δ |
| 42 | 20 | 10 | 100 | Δ |
| 43 | 20 | 10 | 500 | Δ |
| 44 | 20 | 10 | 1000 | Δ |
| 45 | 20 | 10 | 3000 | Δ |
| 46 | 20 | 10 | 5000 | Δ |

### (b) Test Results

In each pulling test performed under the conditions shown in Table 1, a visual inspection was made for all the silicon wafers obtained from each silicon single crystal, and an incidence rate of the micro defects observed in the wafer surface was evaluated. The evaluation was performed based on the incidence rate of the micro defects in all the wafers obtained from the silicon single crystal of Test No. 1. In Table 1, a symbol “Δ” indicates the case in which the incidence rate of the micro defects was less than that of Test No. 1, and a symbol “∘” indicates the case in which the incidence of the micro defects was not observed.

### <Test Nos. 2 to 10>

The evaluations were performed to the silicon wafers formed under the conditions that the rotation rate of the quartz crucible was kept at 0.1 rpm, the alternated rotation period ranged from 5 to 600 sec, and the magnetic field intensity ranged from 0 to 5000 Gauss. A small number of micro defects were observed in the silicon wafers of Test Nos. 2 to 10 which were inventive examples. This is attributed to the fact that the shearing force was not sufficiently generated in the interface between the quartz crucible and the silicon melt and the neighborhood of the interface since the rotation rate of the quartz crucible is as low as 0.1 rpm. However, in Test Nos. 2 to 10, the incidence rate of the micro defects was lower than that of Test No. 1 which was a comparative example.

### <Test Numbers 11 to 19>

The evaluations were performed to the silicon wafers formed under the conditions that the rotation rate of the quartz crucible was kept at 0.5 rpm, the alternated rotation period ranged from 5 to 600 sec, and the magnetic field intensity ranged from 0 to 5000 Gauss. In the silicon wafers of Test Nos. 12 to 18 which were the inventive examples, the micro defect was not observed and the effectiveness of the quartz crucible rotation associated with the alternated rotation could be confirmed. A small number of micro defects were observed in the silicon wafers of Test Nos. 11 and 19 which were the inventive examples.

In Test No. 11, it is considered that, since the alternated rotation period is as short as 5 sec, the sufficient flow is not generated in the intervals of the alternated rotations in the silicon melt, and shearing force was not sufficiently generated in the interface between the quartz crucible and the silicon melt and in the neighborhood of the interface at the time of alternating direction of rotation. In Test No. 19, it is considered that, since the magnetic field intensity is as large as 5000 Gauss, vibration is generated in pulling the silicon single crystal due to the rugged inner surface of the quartz crucible that was generated. Yet, in Test Nos. 11 and 19, the incidence rate of the micro defects was lower than that of Test No. 1.

### <Test Nos. 20 to 28 and 29 to 37>

The evaluations were performed to the silicon wafers formed under the following conditions: for Test Nos. 20 to 28, the rotation rate of the quartz crucible was kept at 5 rpm, the alternated rotation period ranged from 5 to 600 sec, and the magnetic field intensity ranged from 0 to 5000 Gauss; for Test Nos. 29 to 37, the rotation rate of the quartz crucible was kept at 15 rpm, the alternated rotation period ranged from 5 to 600 sec, and the magnetic field intensity ranged from 0 to 5000 Gauss. In the silicon wafers of Test Nos. 20 to 27 and 29 to 36 which were the inventive examples, any micro defect was not observed irrespective of the alternated rotation period and the effectiveness of the quartz crucible rotation accompanying alternating direction of rotation could be confirmed. A small number of micro defects were observed in the silicon wafers of Test Nos. 28 and 37 which were the inventive examples. This is attributed to the same reason as Test No. 19 since the magnetic field intensity is as large as 5000 Gauss. Yet, in Test Nos. 28 and 37, the incidence rate of the micro defects was lower than that of Test No. 1.

### <Test Nos. 38 to 46>

The evaluations were performed to the silicon wafers formed under the conditions that the rotation rate of the quartz crucible was kept at 20 rpm, the alternated rotation period ranged from 5 to 600 sec, and the magnetic field intensity ranged from 0 to 5000 Gauss. A small number of micro defects were observed in the silicon wafers of Test Nos. 38 to 46 which were the inventive examples. This is attributed to the fact that the silicon melt flow was largely disturbed due to the rapid rotation, and the bubbles adhering to the inner surface of the quartz crucible were not sufficiently taken off. Yet, in Test Nos. 38 to 46, the incidence rate of the micro defects was lower than that of Test No. 1.

According to the silicon single crystal pulling method of the present invention, before pulling the silicon single crystal is started, the bubbles adhering to the inner surface of the quartz crucible are taken off, and the bubbles can be removed from the silicon melt. Therefore, the micro defects caused by the bubbles in the silicon single crystal and the dislocation in the silicon single crystal can be reduced without lowering the efficiency of the silicon single crystal growth in the growing process.

Consequently, the silicon single crystal pulling method of the invention can suitably applied for growing the silicon single crystal which is of the source material of the semiconductor silicon wafer.

What is claimed is:

1. A silicon single crystal pulling method performed by the Czochralski method, wherein a quartz crucible containing silicon melt is rotated while a rotating direction thereof is periodically alternated until pulling a silicon single crystal is started after silicon raw materials filled in the quartz crucible are melted.

2. The silicon single crystal pulling method according to claim 1, wherein a rotation rate of the quartz crucible ranges from 5 rpm to 15 rpm.

3. The silicon single crystal pulling method according to claim 1, wherein a rotation rate of the quartz crucible ranges from 0.5 rpm to 15 rpm, and an alternated rotation period of the quartz crucible is equal to or more than 10 sec.

4. The silicon single crystal pulling method according to claim 1, wherein a magnetic field is applied to the quartz crucible.

5. The silicon single crystal pulling method according to claim 2, wherein a magnetic field is applied to the quartz crucible.

6. The silicon single crystal pulling method according to claim 3, wherein a magnetic field is applied to the quartz crucible.

7. The silicon single crystal pulling method according to claim 4, wherein the intensity of the magnetic field applied to the quartz crucible ranges from 100 Gauss to 3000 Gauss.

8. The silicon single crystal pulling method according to claim 5, wherein the intensity of the magnetic field applied to the quartz crucible ranges from 100 Gauss to 3000 Gauss.

9. The silicon single crystal pulling method according to claim 6, wherein the intensity of the magnetic field applied to the quartz crucible ranges from 100 Gauss to 3000 Gauss.
